(19) United States
(12) Patent Application Publication
(10) Pub. No.: US 2025/0221045 A1
(43) Pub. Date: Jul. 3, 2025

(54) DISPLAY DEVICE

(71) Applicant: LG Display Co., Ltd., Seoul (KR)

(72) Inventors: YoungIn JANG, Seoul (KR); Soyoung LEE, Seoul (KR); HyunGon KIM, Seoul (KR); Juhyun NAM, Seoul (KR)

(21) Appl. No.: 18/933,644

(22) Filed: Oct. 31, 2024

(30) Foreign Application Priority Data
Dec. 27, 2023 (KR) 10-2023-0192171

(51) Int. Cl. H01L 27/12; H01L 25/16

(52) U.S. Cl. CPC H10D 86/60; H01L 25/167; H10D 86/441

(57) ABSTRACT

The present disclosure describes various embodiments of a display device. In one embodiment, a display device includes a display panel, a light emitting diode which is disposed in the display panel. The light emitting diode is configured to be controlled in response to an emission period and a non-emission period. The display device includes a driving transistor coupled to the light emitting diode. The display device includes an emission control circuit which is coupled between the light emitting diode and a high potential power line and between the light emitting diode and a low potential power line, in which the emission control circuit is configured to couple the light emitting diode to any one of the high potential power line and the low potential power line in response to each of the emission period and the non-emission period.

### CROSS-REFERENCE TO RELATED APPLICATIONS

This application claims the priority of Korean Patent Application No. 10-2023-0192171 filed on Dec. 27, 2023, in the Korean Intellectual Property Office, the disclosure of which is incorporated herein by reference.

### BACKGROUND

### Technical Field

The present disclosure relates to a display device, and more particularly, to a display device with an improved display quality.

### Description of the Related Art

As display devices which are used for a monitor of a computer, a television, or a cellular phone, there are an organic light emitting display (OLED) device which is a self-emitting device, a liquid crystal display (LCD) device which requires a separate light source, and the like.

An applicable range of the display device is diversified to personal digital assistants as well as monitors of computers and televisions and a display device with a large display area and a reduced volume and weight is being studied.

In recent years, a display device including an LED is attracting attention as a next generation display device. Since the LED is formed of an inorganic material, rather than an organic material, reliability is excellent so that a lifespan thereof is longer than that of the liquid crystal display device or the organic light emitting display device. Further, the LED has a fast lighting speed, excellent luminous efficiency, and a strong impact resistance so that a stability is excellent and an image having a high luminance can be displayed.

### BRIEF SUMMARY

Various embodiments of the present disclosure provide a display device which controls a light emitting diode to emit light only during an emission period.

Various embodiments of the present disclosure provide a display device which suppresses a defect that the light emitting diode emits light during a non-emission period.

Various embodiments of the present disclosure provide a display device which suppresses the light emitting diode from emitting light during the non-emission period to improve a quality of a black image.

Various embodiments of the present disclosure provide a display device which includes an emission control element to suppress the light emitting diode from emitting light during the non-emission period.

Various embodiments of the present disclosure provide a display device which uses a diode as an emission control element.

Various embodiments of the present disclosure provide a display device which uses a transistor in a diode-connection state as an emission control element.

Technical benefits of the present disclosure are not limited to the above-mentioned benefits, and other benefits, which are not mentioned above, can be clearly understood by those skilled in the art from the following descriptions.

In order to achieve the benefits as described above, according to an aspect of the present disclosure, a display device includes a display panel which includes a plurality of sub pixels; a light emitting diode which is disposed in each of the plurality of sub pixels and is configured to be controlled in response to an emission period and a non-emission period; a driving transistor connected to a first electrode of the light emitting diode; and an emission control circuit which is connected between a second electrode of the light emitting diode and a high potential power line and between the second electrode and a low potential power line, in which the emission control circuit is configured to connect the second electrode of the light emitting diode to any one of the high potential power line and the low potential power line in response to each of the emission period and the non-emission period, and the emission control circuit includes an emission control element which is formed by any one of a diode or a transistor in a diode connection state and an emission control transistor. Accordingly, a defect that during the non-emission period, a high potential power voltage is applied to the second electrode so that a light emitting diode abnormally emits light during the non-emission period may be suppressed.

Other detailed matters of the exemplary embodiments are included in the detailed description and the drawings.

According to the present disclosure, the display device may control the light emitting diode to emit light only during the emission period.

According to the present disclosure, the display device may suppress a defect that the light emitting diode emits light during a non-emission period.

According to the present disclosure, the display device may improve a quality of a black image by suppressing the light emitting diode from emitting light during a non-emission period.

According to the present disclosure, the display device may suppress the light emitting diode from abnormally emitting light using a diode.

According to the present disclosure, the display device may suppress the light emitting diode from abnormally emitting light using a transistor in a diode-connection state.

The effects of the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a schematic diagram of a display device according to an exemplary embodiment of the present disclosure;

FIG. 2A is a partial cross-sectional view of a display device according to an exemplary embodiment of the present disclosure;

FIG. 2B is a perspective view of a tiling display device according to an exemplary embodiment of the present disclosure;

FIG. 3 is a circuit diagram of a sub pixel of a display device according to an exemplary embodiment of the present disclosure;

FIG. 4 is a driving timing diagram of a sub pixel of a display device according to an exemplary embodiment of the present disclosure;

FIG. 5 is a simulation result for explaining an effect of improving a raised black phenomenon of a sub pixel of a display device according to an exemplary embodiment of the present disclosure;

FIG. 6 is a plan view of a sub pixel of a display device according to an exemplary embodiment of the present disclosure;

FIG. 7 is a cross-sectional view of a sub pixel of a display device according to an exemplary embodiment of the present disclosure;

FIG. 8 is a circuit diagram of a sub pixel of a display device according to another exemplary embodiment of the present disclosure;

FIG. 9 is a plan view of a sub pixel of a display device according to another exemplary embodiment of the present disclosure; and

FIG. 10 is a cross-sectional view of a sub pixel of a display device according to another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, numbers, and the like illustrated in the accompanying drawings for describing the exemplary embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

The features of various embodiments of the present disclosure can be partially or entirely adhered to or combined with each other and can be interlocked and operated in technically various ways, and the embodiments can be carried out independently of or in association with each other.

Hereinafter, exemplary embodiments of the present disclosure will be described in detail with reference to accompanying drawings.

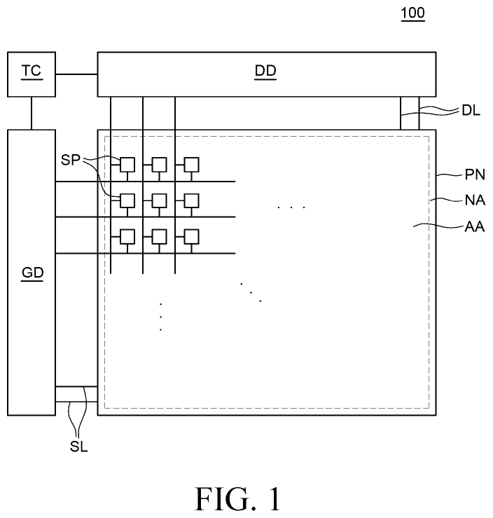

FIG. 1 is a schematic diagram of a display device according to an exemplary embodiment of the present disclosure. In FIG. 1, for the convenience of description, among various components of the display device, only a display panel PN, a gate driver GD, a data driver DD, and a timing controller TC are illustrated.

Referring to FIG. 1, the display device includes a display panel PN including a plurality of sub pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL according to a plurality of gate control signals supplied from the timing controller TC. Even though in FIG. 1, it is illustrated that one gate driver GD is disposed to be spaced apart from one side of the display panel PN, the number of the gate drivers GD and the placement thereof are not limited thereto.

The data driver DD supplies a data voltage to a plurality of data lines DL according to a plurality of data control signals and image data supplied from the timing controller TC. The data driver DD may convert the image data into a data voltage using a reference gamma voltage and supply the converted data voltage to the plurality of data lines DL.

The timing controller TC aligns image data input from the outside to supply the image data to the data driver DD. The timing controller TC may generate a gate control signal and a data control signal using synchronization signals input from the outside, such as a dot clock signal, a data enable signal, and horizontal/vertical synchronization signals. The timing controller TC supplies the generated gate control signal and data control signal to the gate driver GD and the data driver DD, respectively, to control the gate driver GD and the data driver DD.

The display panel PN is a configuration which displays images to the user and includes the plurality of sub pixels SP. In the display panel PN, the plurality of scan lines SL and the plurality of data lines DL intersect each other and the plurality of sub pixels SP may be formed at intersections of the scan lines SL and the data lines DL.

In the display panel PN, an active area AA and a non-active area NA may be defined.

The active area AA is an area in which images are displayed in the display device 100. In the active area AA, a plurality of sub pixels SP which configures a plurality of pixels PX and a pixel circuit for driving the plurality of sub pixels SP may be disposed. The plurality of sub pixels SP is a minimum unit which configures the active area AA and n sub pixels SP may form one pixel PX. In each of the plurality of sub pixels SP, a thin film transistor for driving the plurality of light emitting diodes 120 may be disposed. The plurality of light emitting diodes 120 may be defined in different ways depending on the type of the display panel PN. For example, when the display panel PN is an inorganic light emitting display panel PN, the light emitting diode 120 may be a light emitting diode (LED) or a micro light emitting diode (micro LED).

In the active area AA, a plurality of signal lines which transmits various signals to the plurality of sub pixels SP is disposed. For example, the plurality of signal lines may include a plurality of data lines DL which supplies a data voltage to each of the plurality of sub pixels SP and a plurality of scan lines SL which supplies a scan signal to each of the plurality of sub pixels SP. The plurality of scan lines SL extends to one direction in the active area AA to be connected to the plurality of sub pixels SP and the plurality of data lines DL extends to a direction different from the one direction in the active area AA to be connected to the plurality of sub pixels SP. In addition, in the active area AA, a low potential power line VSS, a high potential power line VDD, and the like may be further disposed, but are not limited thereto.

The non-active area NA is an area where images are not displayed so that the non-active area NA may be defined as an area extending from the active area AA. In the non-active area NA, a link line which transmits a signal to the sub pixel SP of the active area AA, a pad electrode, or a driving IC, such as a gate driver IC or a data driver IC, may be disposed.

In the meantime, the non-active area NA may be located on a rear surface of the display panel PN, that is, a surface on which the sub pixels SP are not disposed or may be omitted, and is not limited as illustrated in the drawing.

In the meantime, a driver, such as a gate driver GD, a data driver DD, and a timing controller TC, may be connected to the display panel PN in various ways. For example, the gate driver GD may be mounted in the non-active area NA in a gate in panel (GIP) manner or mounted between the plurality of sub pixels SP in the active area AA in a gate in active area (GIA) manner.

For example, the data driver DD and the timing controller TC are formed in separate flexible film and printed circuit board. The display panel PN may be electrically connected to the data driver DD and the timing controller TC by bonding the flexible film and the printed circuit board to the pad electrode formed in the non-active area NA of the display panel PN.

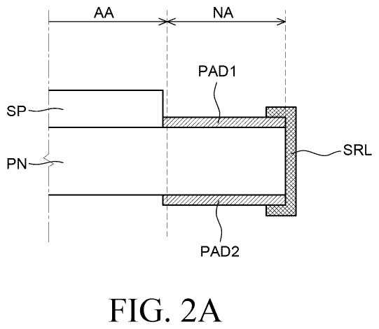

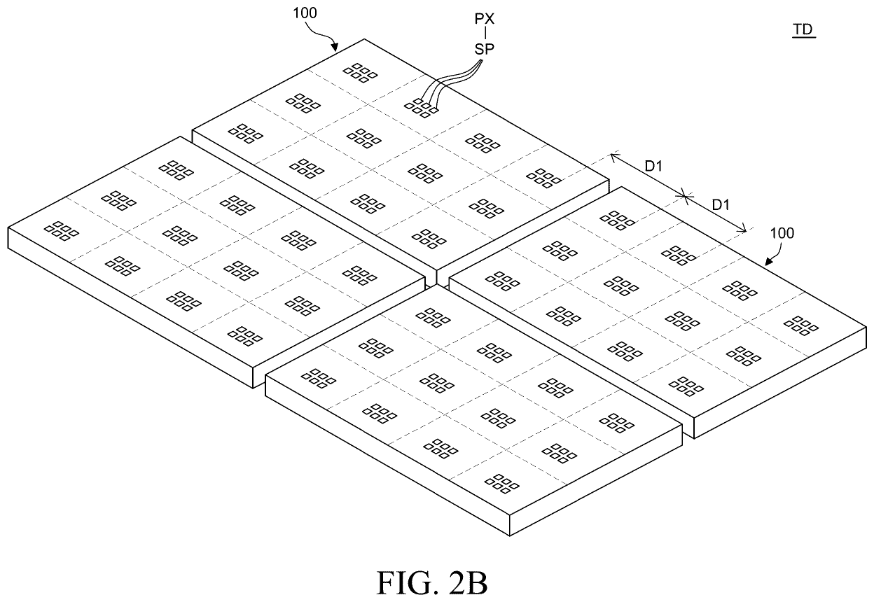

As another example, when the gate driver GD is mounted in the active area AA in the GIA manner and a side line SRL which connects the signal line on the front surface of the display panel PN to the pad electrode on a rear surface of the display panel PN is formed to bond the flexible film and the printed circuit board onto a rear surface of the display panel PN, the non-active area NA may be minimized on the front surface of the display panel PN. Therefore, when the gate driver GD, the data driver DD, and the timing controller TC are connected to the display panel PN as described above, a zero bezel in which there is no bezel may be substantially implemented, which will be described in more detail with reference to FIGS. 2A and 2B.

FIG. 2A is a partial cross-sectional view of a display device according to an exemplary embodiment of the present disclosure. FIG. 2B is a perspective view of a tiling display device according to an exemplary embodiment of the present disclosure.

In the non-active area NA of the display panel PN, a plurality of pad electrodes for transmitting various signals to the plurality of sub pixels SP is disposed. For example, in a non-active area NA on the front surface of the display panel PN, a first pad electrode PAD1 which transmits a signal to the plurality of sub pixels SP is disposed. In a non-active area NA on the rear surface of the display panel PN, a second pad electrode PAD2 which is electrically connected to a driving component, such as a flexible film and the printed circuit board, is disposed.

In this case, even though it is not illustrated in the drawing, various signal lines connected to the plurality of sub pixels SP, for example, a scan line SL or a data line DL extends from the active area AA to the non-active area NA to be electrically connected to the first pad electrode PAD1.

The side line SRL is disposed along a side surface of the display panel PN. The side line SRL may electrically connect the first pad electrode PAD1 on the front surface of the display panel PN and the second pad electrode PAD2 on the rear surface of the display panel PN. Therefore, a signal from a driving component on the rear surface of the display panel PN may be transmitted to the plurality of sub pixels SP through the second pad electrode PAD2, the side line SRL, and the first pad electrode PAD1. Accordingly, a driving component is disposed on a rear surface of the display panel PN and a signal transmission path between the front surface and the rear surface of the display panel PN is formed to minimize a size of the non-active area NA on the front surface of the display panel PN.

Referring to FIG. 2B, a tiling display device TD having a large screen size may be implemented by connecting a plurality of display devices 100. At this time, as illustrated in FIG. 2A, when the tiling display device TD is implemented using a display device 100 with a minimized bezel, a seam area in which an image between the display devices 100 is not displayed is minimized so that a display quality may be improved.

For example, the plurality of sub pixels SP may form one pixel PX and a distance D1 between an outermost pixel PX of one display device 100 and an outermost pixel PX of another display device 100 adjacent to one display device may be implemented to be equal to a distance D1 between pixels PX in one display device 100. Accordingly, the distance between pixels PX between the display devices 100 is constantly configured to minimize the seam area.

However, FIGS. 2A and 2B are illustrative so that the display device 100 according to the exemplary embodiment of the present disclosure may be a general display device with a bezel, but is not limited thereto.

Hereinafter, a display panel PN of a display device 100 according to an exemplary embodiment of the present disclosure will be described in more detail.

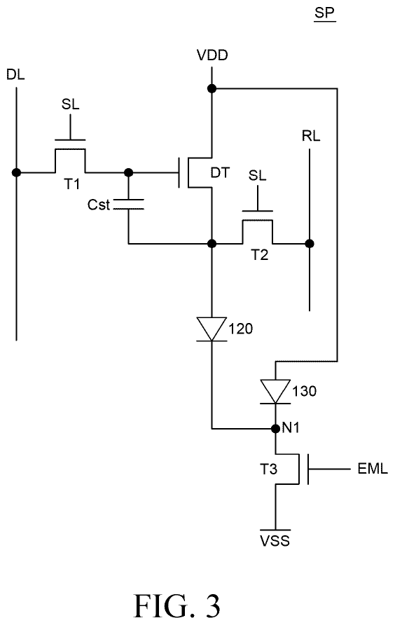

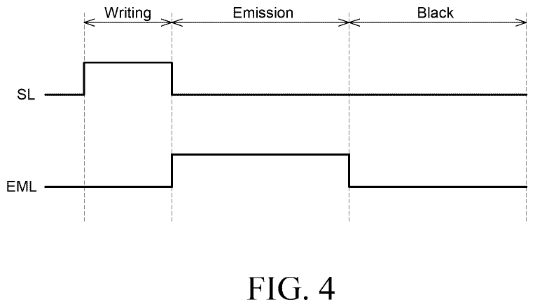

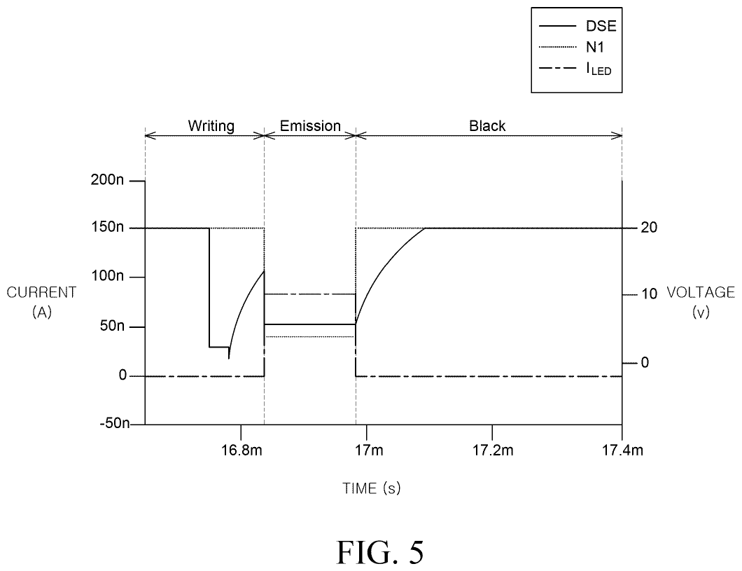

FIG. 3 is a circuit diagram of a sub pixel of a display device according to an exemplary embodiment of the present disclosure. FIG. 4 is a driving timing diagram of a sub pixel of a display device according to an exemplary embodiment of the present disclosure. FIG. 5 is a simulation result for explaining an effect of improving a raised black phenomenon of a sub pixel of a display device according to an exemplary embodiment of the present disclosure. Specifically, FIG. 5 illustrates a result of measuring voltages and driving currents I_{LED} of a driving source electrode DSE of a light emitting diode 120 and a first node N1 during a driving period of the display device 100.

Referring to FIG. 3, each of the plurality of sub pixels SP includes a first transistor T1, a second transistor T2, a third transistor T3, a driving transistor DT, a storage capacitor Cst, an emission control element 130, and a light emitting diode 120. Each of the plurality of sub pixels SP is connected to a scan line SL, a data line DL, an emission control line EML, a reference line RL, a high potential power line VDD, and a low potential power line VSS to be driven.

First, the first transistor T1, the second transistor T2, the third transistor T3, and the driving transistor DT of each of the plurality of sub pixels SP include gate electrodes, source electrodes, and drain electrodes. The first transistor T1, the second transistor T2, the third transistor T3, and the driving transistor DT may be P-type transistors or N-type transistors. For example, since in the P-type transistor, holes move from the source electrode to the drain electrode, the current may flow from the source electrode to the drain electrode. Since in the N-type transistor, electrons move from the source electrode to the drain electrode, the current may flow from the drain electrode to the source electrode. Hereinafter, the description will be made under the assumption that the first transistor T1, the second transistor T2, the third transistor T3, and the driving transistor DT are N-type transistors in which the current flows from the drain electrode to the source electrode, but the present disclosure is not limited thereto.

The driving transistor DT is a transistor which controls a driving current I_{LED} supplied to the light emitting diode 120. The driving transistor DT includes a driving gate electrode DGE connected to the first transistor T1, a driving drain electrode DDE connected to the high potential power line VDD, and a driving source electrode DSE connected to the light emitting diode 120. The driving transistor DT is turned on to control a driving current I_{LED} flowing to the light emitting element 120.

The first transistor T1 is a transistor which transmits a data voltage to the gate electrode of the driving transistor DT. The first transistor T1 includes a first gate electrode GE1 connected to the scan line SL, a first drain electrode DE1 connected to the data line DL, and a first source electrode SE1 connected to the driving gate electrode DGE of the driving transistor DT. The first transistor T1 may be turned on by a signal from the scan line SL and a data voltage from the data line DL may be transmitted to the driving gate electrode DGE of the driving transistor DT through the turned-on first transistor T1. Accordingly, the first transistor T1 may be referred to as a switching transistor.

The second transistor T2 is a transistor which compensates for a threshold voltage of the driving transistor DT. The second transistor T2 is connected between the driving source electrode DSE of the driving transistor DT and the reference line RL. The second transistor T2 includes a second gate electrode GE2 connected to the scan line SL and a second source electrode SE2 and a second drain electrode DE2 which are connected to the driving source electrode DSE of the driving transistor DT and the reference line RL, respectively. The second transistor T2 is turned on to transmit a reference voltage to the driving source electrode DSE of the driving transistor DT to sense a threshold voltage of the driving transistor DT. Accordingly, the second transistor T2 which senses a characteristic of the driving transistor DT may be referred to as a sensing transistor.

The third transistor T3 is a transistor for controlling an emission period of the light emitting diode 120. The third transistor T3 includes a third gate electrode GE3 connected to the emission control line EML, a third drain electrode DE3 connected to the first node N1, and a third source electrode SE3 connected to a low potential power line VSS. The third transistor T3 may be turned on by the emission control signal from the emission control line EML and the first node N1 and the low potential power line VSS may be electrically connected through the turned-on third transistor T3. The third transistor T3 which controls the emission of the light emitting diode 120 may be referred to as an emission control transistor. The third transistor T3 may also be referred to as an emission control circuit which controls the emission of the light emitting diode 120 together with the emission control element 130 to be described below.

The storage capacitor Cst stores a potential difference between the driving gate electrode DGE and the driving source electrode DSE of the driving transistor DT while the light emitting diode 120 emits light to supply a constant driving current I_{LED} to the light emitting diode 120. The storage capacitor Cst includes a plurality of capacitor electrodes. Some electrodes of the storage capacitor Cst may be connected to the driving gate electrode DGE of the driving transistor DT and the other electrodes of the storage capacitor Cst may be connected to the driving source electrode DSE of the driving transistor DT.

The light emitting diode 120 is disposed in each of the plurality of sub pixels SP. The light emitting diode 120 is an element which emits light by the driving current I_{LED}. The light emitting diode 120 may include a light emitting diode 120 which emits red light, green light, and blue light and implement various color light including white by a combination thereof. Further, various color light may be implemented using the light emitting diode 120 which emits specific color light and a light conversion member which converts light from the light emitting diode 120 into another color light. The light emitting diode 120 may be an LED or a micro LED.

The light emitting diode 120 includes a first electrode 124 connected to the driving source electrode DSE of the driving transistor DT and a second electrode 125 connected to the first node N1. The first electrode 124 and the second electrode 125 may be referred to as an anode and a cathode, respectively. The light emitting diode 120 is supplied with a driving current I_{LED} from the driving transistor DT to emit light.

The emission control element 130 is disposed in each of the plurality of sub pixels SP. The emission control element 130 is connected between the high potential power line VDD and the first node N1 to flow current only to the first node N1 from the high potential power line VDD. The emission control element 130 may serve as a diode which controls the current to flow only in one direction. If the third transistor T3 is turned off so that the first node N1 and the low potential power line VSS are separated, a voltage of the first node N1 may become a high potential power voltage by the emission control element 130 which connects the high potential power line VDD and the first node N1. In contrast, when the third transistor T3 is turned on, the voltage of the first node N1 may be converged to the low potential power voltage.

The emission control circuit which is configured by the emission control element 130 and the third transistor T3 is configured to connect the second electrode 125 of the light emitting diode 120 to any one of the high potential power line VDD and the low potential power line VSS in response to each of the emission period Emission and the non-emission period Black. For example, the emission control circuit configured by the emission control element 130 and the third transistor T3 may suppress a defect that the second electrode 125 of the light emitting diode 120 is connected to the high potential power line VDD during the non-emission period Black so that the light emitting diode 120 emits light. For example, the emission control circuit configured by the emission control element 130 and the third transistor T3 connects the second electrode 125 of the light emitting diode 120 to the low potential power line VSS during the emission period Emission to control the light emitting diode 120 to emit light. Accordingly, the emission control circuit configured by the emission control element 130 and the third transistor T3 may allow the light emitting diode 120 to emit light only during the emission period Emission.

The emission control element 130 may be configured by various types of elements. For example, the emission control element 130 may be configured by a diode. Hereinafter, it is described that the emission control element 130 of the display device 100 according to the exemplary embodiment of the present disclosure is configured by a diode 130.

The diode 130 is an element which allows a current to flow only in one direction. A first diode electrode 133 and a second diode electrode 134 of the diode 130 are connected to the high potential power line VDD and the first node N1, respectively, to flow the current from the high potential power line VDD to the first node N1. Further, during a period when the third transistor T3 is turned off, a voltage of the first node N1 may become the high potential power voltage.

Next, referring to FIG. 4, the sub pixel SP may be driven in any one of a data writing period Writing, an emission period Emission, and a non-emission period Black. When an image is displayed in a sub pixel SP, the sub pixel SP may be driven in the order of the data writing period Writing and the emission period Emission. In a period when the image is not displayed in the sub pixel SP, that is, in the non-emission period Black, the sub pixel SP may not be substantially driven.

First, the data writing period Writing is a period when a data voltage is written in the sub pixel SP before displaying the image in the sub pixel SP. During the data writing period Writing, a data voltage corresponding to the image may be applied to the sub pixel SP.

Referring to FIGS. 3 and 4 together, during the data writing period Writing, a turn-on level of scan signal is applied to the scan line SL. The first transistor T1 is turned on by the scan signal to apply a data voltage from the data line DL to the driving gate electrode DGE. The second transistor T2 is turned on by the scan signal to apply the reference voltage from the reference line RL to the driving source electrode DSE. Accordingly, the storage capacitor Cst stores a different voltage between a data voltage applied to the driving gate electrode DGE and the reference voltage applied to the driving source electrode DSE to allow a constant driving current I_{LED} to be supplied from the driving transistor DT to the light emitting diode 120 during the emission period Emission thereafter.

During the data wiring period Writing, a turn-off level of emission control signal is applied to the emission control line EML. During the data writing period Writing, the third transistor T3 may be turned off and a voltage of the first node N1 may become a high potential power voltage by the diode 130 which connects the first node N1 and the high potential power line VDD. Accordingly, during the data writing period Writing, a voltage of the second electrode 125 of the light emitting diode 120 may become the high potential power voltage.

Next, the emission period Emission is a period when the light emitting diode 120 of the sub pixel SP emits light. During the emission period Emission, the light emitting diode 120 is supplied with a driving current I_{LED} from the driving transistor DT to emit light.

During the emission period Emission, a turn-off level of scan signal is applied to the scan line SL and a turn-on level of emission control signal is applied to the emission control line EML. Therefore, the first transistor T1 and the second transistor T2 may be turned off and the third transistor T3 may be turned off. As the third transistor T3 is turned on, a voltage of the first node N1 may become a low potential power voltage and a voltage of the second electrode 125 of the light emitting diode 120 may be set to a low potential power voltage. As a voltage of the second electrode 125 of the light emitting diode 120 is set to a low potential power voltage, a voltage of the first electrode 124 of the light emitting diode 120 may be higher than a voltage of the second electrode 125 of the light emitting diode 120. The driving current I_{LED} may easily flow from the first electrode 124 to the second electrode 125 of the light emitting diode 120. Accordingly, during the emission period Emission, the driving current I_{LED} flows from the first electrode 124 to the second electrode 125 so that the light emitting diode 120 emits light.

Finally, during the non-emission period Black, a turn-off level of scan signal is applied to the scan line SL and a turn-off level of emission control signal is applied to the emission control line EML. During the non-emission period Black, all the first transistor T1, the second transistor T2, and the third transistor T3 may be turned off. Further, as a voltage of the second electrode 125 of the light emitting diode 120 is set to a high potential power voltage, the light emitting diode 120 may be suppressed from emitting light. Accordingly, during the non-emission period Black, all the first transistor T1, the second transistor T2, and the third transistor T3 are turned off and the voltage of the second electrode 125 of the light emitting diode 120 is set to a high potential power voltage to control the light emitting diode 120 so as not to emit light.

In the meantime, in the related art, the emission control transistor is disposed between the driving transistor and the light emitting diode and the light emitting diode is connected between the emission control transistor and the low potential power line. At this time, in some cases, a parasitic capacitor is formed in the emission control transistor, by configurations disposed in the vicinity of the emission control transistor. A kick-back phenomenon that a voltage of a node around the emission control transistor, for example, a voltage of the driving source electrode is distorted due to the parasitic capacitor formed in the emission control transistor is caused. Specifically, the larger the size of the emission control transistor, the more severe the kick-back phenomenon.

There is a case that a high voltage is momentarily applied to the driving source electrode due to the kick-back phenomenon generated in the emission control transistor. A light emitting diode configured by a micro LED or an LED has a turn-on voltage lower than that of the organic light emitting diode. Therefore, in a remaining period excluding the emission period, a high voltage is applied to the driving source electrode due to the kick-back phenomenon so that a driving current may flow to the light emitting diode having a low turn-on voltage. Therefore, there is a problem in that in a period other than the emission period, the light emitting diode emits light. Specifically, there is a defect that during the data writing period when various voltages are applied to the sub pixel, the light emitting diode emits light, so that a black image is not appropriately displayed in the sub pixel and the display quality is degraded.

Therefore, in the display device 100 according to the exemplary embodiment of the present disclosure, only during the emission period Emission, the second electrode 125 of the light emitting diode 120 is connected to the low potential power line VSS. By doing this, the defect that the light emitting diode 120 emits light in a period other than the emission period Emission may be suppressed. Specifically, the third transistor T3 which serves as the emission control transistor is disposed between the second electrode 125 of the light emitting diode 120 and the low potential power line VSS. Further, the emission control element 130 is disposed between the second electrode 125 of the light emitting diode 120 and the high potential power line VDD. In the period other than the emission period Emission, for example, in the data writing period Writing and the non-emission period Black, the emission control element 130 applies the high potential power voltage to the second electrode 125 of the light emitting diode 120 to suppress the current from flowing from the first electrode 124 to the second electrode 125 of the light emitting diode 120. During the emission period Emission, the third transistor T3 connects the second electrode 125 of the light emitting diode 120 to the low potential power line VSS to control the driving current I_{LED} to flow from the first electrode 124 to the second electrode 125 of the light emitting diode 120.

Referring to FIG. 5, it is confirmed that as a driving simulation result of the sub pixel SP, during the data writing period Writing and the non-emission period Black, the third transistor T3 is turned off to set a voltage of the first node N1, that is, a voltage of the second electrode 125 of the light emitting diode 120 to a high potential power voltage.

It is confirmed that during the data writing period Writing and the non-emission period Black, a voltage of the driving source electrode DSE, that is, the voltage of the first electrode 124 of the light emitting diode 120 is equal to or lower than the voltage of the second electrode 125. When the voltage of the first electrode 124 is equal to or lower than the voltage of the second electrode 125, the driving current I_{LED} cannot flow from the first electrode 124 to the second electrode 125 and the light emitting diode 120 cannot emit light. Accordingly, it is confirmed that during the data writing period Writing and the non-emission period Black, the driving current I_{LED} may also be 0 A. Therefore, a defect that the light emitting diode 120 emits light due to the kick-back phenomenon during the data writing period Writing and the non-emission period Black may be suppressed. Specifically, the raised black phenomenon that the light emitting diode 120 emits light during the non-emission period Black so that the black image is not appropriately displayed may be suppressed.

Further, it is confirmed that during the emission period Emission, the third transistor T3 is turned on to set a voltage of the first node N1, that is, a voltage of the second electrode 125 of the light emitting diode 120 to a low potential power voltage. It is confirmed that as the voltage of the second electrode 125 is set to be lower than the voltage of the first electrode 124 during the emission period Emission, the driving current I_{LED} flows to the light emitting diode 120. Accordingly, only during the emission period Emission, the driving current I_{LED} normally flows so that the light emitting diode 120 may emit light.

Therefore, in the display device 100 according to the exemplary embodiment of the present disclosure, the third transistor T3 and the emission control element 130 which serve as the emission control circuit are connected to the second electrode 125 of the light emitting diode 120. Accordingly, any one of the low potential power voltage and the high potential power voltage may be supplied to the second electrode 125 of the light emitting diode 120 depending on the driving period. Therefore, in a period other than the emission period Emission, the high potential power voltage is supplied to the second electrode 125 of the light emitting diode 120 to suppress the raised black phenomenon caused by the light emitting diode 120 which emits light and improve the display quality.

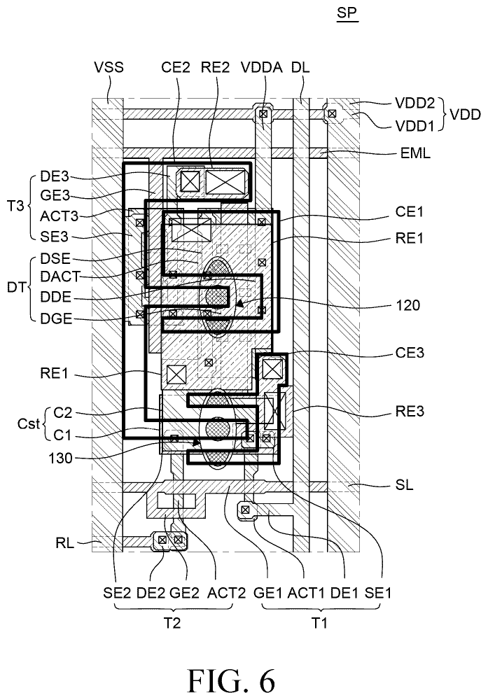

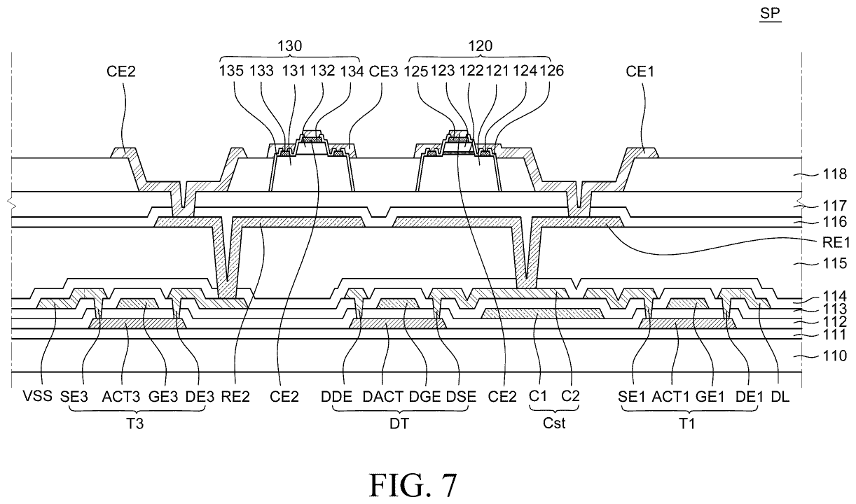

Hereinafter, a structure of a sub pixel SP of the display device 100 according to the exemplary embodiment of the present disclosure will be described in more detail with reference to FIGS. 6 and 7.

FIG. 6 is a plan view of a sub pixel of a display device according to an exemplary embodiment of the present disclosure. FIG. 7 is a cross-sectional view of a sub pixel of a display device according to an exemplary embodiment of the present disclosure.

Referring to FIGS. 6 and 7, the substrate 110 is a component for supporting various components included in the display device 100 and may be formed of an insulating material. For example, the substrate 110 may be formed of glass or resin. Further, the substrate 110 may be configured to include a polymer or plastics or may be formed of a material having flexibility.

A buffer layer 111 is disposed on the substrate 110. The buffer layer 111 may reduce permeation of moisture or impurities through the substrate 110. The buffer layer 111 may be configured by a single layer or a double layer of silicon oxide (SiOx) or silicon nitride (SiNx), but is not limited thereto. However, the buffer layer 111 may be omitted depending on a type of substrate 110 or a type of transistor, but is not limited thereto.

The driving transistor DT is disposed on the buffer layer 111. The driving transistor DT includes a driving active layer DACT, a driving gate electrode DGE, a driving source electrode DSE, and a driving drain electrode DDE.

The driving active layer DACT is disposed on the buffer layer 111. The driving active layer DACT may be formed of a semiconductor material, such as an oxide semiconductor, amorphous silicon, or polysilicon, but is not limited thereto.

The gate insulating layer 112 is disposed on the driving active layer DACT. The gate insulating layer 112 is an insulating layer which insulates the driving active layer DACT from the driving gate electrode DGE and may be configured by a single layer or a double layer of silicon oxide (SiOx) or silicon nitride (SiNx), but is not limited thereto.

The driving gate electrode DGE is disposed on the gate insulating layer 112. The driving gate electrode DGE may be electrically connected to the first capacitor electrode C1 of the storage capacitor Cst. The driving gate electrode DGE and the first capacitor electrode C1 are formed on the same layer with the same material and the first capacitor electrode C1 and the driving gate electrode DGE may be integrally formed. The driving gate electrode DGE may be electrically connected to the first source electrode SE1 through a contact hole of the interlayer insulating layer 113. The driving gate electrode DGE may be configured by a conductive material, such as copper (Cu), aluminum (Al), molybdenum (Mo), nickel (Ni), titanium (Ti), chrome (Cr), or an alloy thereof, but is not limited thereto.

The interlayer insulating layer 113 is disposed on the driving gate electrode DGE. The interlayer insulating layer 113 is an insulating layer which protects components below the interlayer insulating layer 113 and may be configured by a single layer or a double layer of silicon oxide (SiOx) or silicon nitride (SiNx), but is not limited thereto.

The driving source electrode DSE and the driving drain electrode DDE are disposed on the interlayer insulating layer 113. The driving source electrode DSE and the driving drain electrode DDE may be electrically connected to a driving active layer DACT through a contact hole of the interlayer insulating layer 113 and the gate insulating layer 112. The driving source electrode DSE may be electrically connected to a first reflective electrode RE1 through a contact hole of a first passivation layer 114 and a first planarization layer 115. The driving source electrode DSE is integrally formed with the second source electrode SE2 to be electrically connected to the second source electrode SE2. The driving drain electrode DDE may be electrically connected to the high potential power line VDD through an auxiliary high potential power line VDDA. The driving source electrode DSE and the driving drain electrode DDE may be configured by a conductive material, such as copper (Cu), aluminum (Al), molybdenum (Mo), nickel (Ni), titanium (Ti), chrome (Cr), or an alloy thereof, but are not limited thereto.

Next, the first transistor T1 is disposed on the buffer layer 111. The first transistor T1 includes a first active layer ACT1, a first gate electrode GE1, a first source electrode SE1, and a first drain electrode DE1.

The first active layer ACT1 is disposed on the buffer layer 111. The first active layer ACT1 may be formed of a semiconductor material such as an oxide semiconductor, amorphous silicon, or polysilicon, but is not limited thereto.

The gate insulating layer 112 is disposed on the first active layer ACT1 and the first gate electrode GE1 is disposed on the gate insulating layer 112. The first gate electrode GE1 may be electrically connected to the scan line SL. The first gate electrode GE1 may be configured by a conductive material, such as copper (Cu), aluminum (Al), molybdenum (Mo), nickel (Ni), titanium (Ti), chrome (Cr), or an alloy thereof, but is not limited thereto.

The interlayer insulating layer 113 is disposed on the first gate electrode GE1 and the first source electrode SE1 and the first drain electrode DE1 are disposed on the interlayer insulating layer 113. The first source electrode SE1 and the first drain electrode DE1 may be electrically connected to the first active layer ACT1 through a contact hole of the interlayer insulating layer 113 and the gate insulating layer 112. The first source electrode SE1 may be electrically connected to the driving gate electrode DGE through a contact hole of the interlayer insulating layer 113. The first drain electrode DE1 may be electrically connected to the data line DL. The first drain electrode DE1 is formed on the same layer with the same material as the data line DL and may be integrally formed with the data line DL. The first source electrode SE1 and the first drain electrode DE1 may be configured by a conductive material, such as copper (Cu), aluminum (Al), molybdenum (Mo), nickel (Ni), titanium (Ti), chrome (Cr), or an alloy thereof, but are not limited thereto.

The second transistor T2 is disposed on the buffer layer 111. The second transistor T2 includes a second active layer ACT2, a second gate electrode GE2, a second source electrode SE2, and a second drain electrode DE2.

The second active layer ACT2 is disposed on the buffer layer 111. The second active layer ACT2 may be formed of a semiconductor material such as an oxide semiconductor, amorphous silicon, or polysilicon, but is not limited thereto.

The gate insulating layer 112 is disposed on the second active layer ACT2 and the second gate electrode GE2 is disposed on the gate insulating layer 112. The second gate electrode GE2 may be electrically connected to the scan line SL. The second gate electrode GE2 may be configured by a conductive material, such as copper (Cu), aluminum (Al), molybdenum (Mo), nickel (Ni), titanium (Ti), chrome (Cr), or an alloy thereof, but is not limited thereto.

The interlayer insulating layer 113 is disposed on the second gate electrode GE2 and the second source electrode SE2 and the second drain electrode DE2 are disposed on the interlayer insulating layer 113. The second source electrode SE2 and the second drain electrode may be electrically connected to the second active layer ACT2 through a contact hole of the interlayer insulating layer 113 and the gate insulating layer 112. The second source electrode SE2 may be integrally formed with the driving source electrode DSE to be electrically connected to the driving source electrode DSE. The second drain electrode DE2 may be electrically connected to the reference line RL through a contact hole of the interlayer insulating layer 113. The second source electrode SE2 and the second drain electrode DE2 may be configured by a conductive material, such as copper (Cu), aluminum (Al), molybdenum (Mo), nickel (Ni), titanium (Ti), chrome (Cr), or an alloy thereof, but are not limited thereto.

The third transistor T3 is disposed on the buffer layer 111. The third transistor T3 includes a third active layer ACT3, a third gate electrode GE3, a third source electrode SE3, and a third drain electrode DE3.

The third active layer ACT3 is disposed on the buffer layer 111. The third active layer ACT3 may be formed of a semiconductor material such as an oxide semiconductor, amorphous silicon, or polysilicon, but is not limited thereto.

The gate insulating layer 112 is disposed on the third active layer ACT3 and the third gate electrode GE3 is disposed on the gate insulating layer 112. The third gate electrode GE3 may be electrically connected to the emission control line EML. The third gate electrode GE3 may be configured by a conductive material, such as copper (Cu), aluminum (Al), molybdenum (Mo), nickel (Ni), titanium (Ti), chrome (Cr), or an alloy thereof, but is not limited thereto.

The interlayer insulating layer 113 is disposed on the third gate electrode GE3 and the third source electrode SE3 and the third drain electrode DE3 are disposed on the interlayer insulating layer 113. The third source electrode SE3 and the third drain electrode DE3 may be electrically connected to the third active layer ACT3 through a contact hole of the interlayer insulating layer 113 and the gate insulating layer 112. The third source electrode SE3 may be electrically connected to the low potential power line VSS. The third source electrode SE3 is formed on the same layer with the same material as the low potential power line VSS and may be integrally formed with the low potential power line VSS. The third drain electrode DE3 may be electrically connected to a second reflective electrode RE2 through a contact hole of the first passivation layer 114 and the first planarization layer 115. The third source electrode SE3 and the third drain electrode DE3 may be configured by a conductive material, such as copper (Cu), aluminum (Al), molybdenum (Mo), nickel (Ni), titanium (Ti), chrome (Cr), or an alloy thereof, but are not limited thereto.

A storage capacitor Cst is disposed on the gate insulating layer 112. The storage capacitor Cst includes a first capacitor electrode C1 and a second capacitor electrode C2.

The first capacitor electrode C1 is disposed on the gate insulating layer 112. The first capacitor electrode C1 may be integrally formed with the driving gate electrode DGE to be electrically connected to the driving gate electrode DGE. The interlayer insulating layer 113 is disposed on the first capacitor electrode C1 and the second capacitor electrode C2 is disposed on the interlayer insulating layer 113. The second capacitor electrode C2 may overlap the first capacitor electrode C1. The second capacitor electrode C2 may be integrally formed with the driving source electrode DSE to be electrically connected to the driving source electrode DSE. Accordingly, the first capacitor electrode C1 connected to the driving gate electrode DGE and the second capacitor C2 connected to the driving source electrode DSE are disposed so as to overlap each other with the interlayer insulating layer 113 therebetween to form the storage capacitor Cst.

Next, the scan line SL, the reference line RL, and the emission control line EML are disposed on the gate insulating layer 112. The scan line SL, the reference line RL, and the emission control line EML are disposed to extend in a row direction and may transmit various signals to configurations disposed in the plurality of sub pixels SP.

For example, the scan line SL may transmit a scan signal to the first transistor T1 and the second transistor T2. The scan line SL is disposed across the sub pixel SP so that a part of the scan line may overlap the first transistor T1 and the second transistor T2. A part of the scan line SL which overlaps the first active layer ACT1 may serve as the first gate electrode GE1 and the other part of the scan line SL which overlaps the second active layer ACT2 may serve as the second gate electrode GE2. Therefore, the scan line SL which is integrally formed with the first gate electrode GE1 and the second gate electrode GE2 may transmit the scan signal to the first gate electrode GE1 and the second gate electrode GE2.

The reference line RL may transmit the reference voltage to the second drain electrode DE2 of the second transistor T2. The reference line RL is disposed across the sub pixel SP so that a part of the reference line may overlap the second transistor T2. For example, the part of the reference line RL may overlap the second drain electrode DE2 and the second drain electrode DE2 and the reference line RL may be electrically connected to each other through a contact hole of the interlayer insulating layer 113.

The emission control line EML may transmit an emission control signal to the third transistor T3. The emission control line EML is disposed across the sub pixel SP so that a part of the emission control line may overlap the third transistor T3. A part of the emission control line EML which overlaps the third active layer ACT3 may serve as the third gate electrode GE3. The third gate electrode GE3 and the emission control line EML may be integrally formed and the emission control line EML may transmit an emission control signal to the third gate electrode GE3.

The low potential power line VSS and the data line DL are disposed on the interlayer insulating layer 113. The low potential power line VSS and the data line DL are disposed to extend in a column direction and may transmit various signals to configurations disposed in the plurality of sub pixels SP.

The low potential power line VSS may transmit a low potential power voltage to the third transistor T3. The low potential power line VSS is disposed in an area between the sub pixels SP and may be connected to the third source electrode SE3 of the third transistor T3. The low potential power line VSS and the third source electrode SE3 may be integrally formed and the low potential power line VSS may transmit the low potential power voltage to the third source electrode SE3.

The data line DL may transmit the data voltage to the first transistor T1. The data line DL is disposed across the sub pixel SP and may be connected to the first drain electrode DE1. The data line DL and the first drain electrode DE1 may be integrally formed with each other and the data line DL may transmit the data voltage to the first drain electrode DE1.

The high potential power line VDD is disposed on the gate insulating layer 112. The high potential power line VDD includes a first high potential power line VDD1 and a second high potential power line VDD2. The first high potential power line VDD1 is disposed on the gate insulating layer 112 and may extend in the row direction. The second high potential power line VDD2 is disposed on the interlayer insulating layer 113 and may extend in the column direction. The first high potential power line VDD1 and the second high potential power line VDD2 may intersect each other and may be electrically connected to each other at the intersecting point. The first high potential power line VDD1 and the second high potential power line VDD2 may form a mesh structure and lower an overall resistance of the high potential power line VDD. Accordingly, the high potential power line VDD is configured by the first high potential power line VDD1 and the second high potential power line VDD2 extending in the row direction and the column direction to minimize the drop of the high potential power voltage.

The auxiliary high potential power line VDDA which electrically connects the high potential power line VDD and the driving transistor DT is disposed on the interlayer insulating layer 113. One end of the auxiliary high potential power line VDDA may be electrically connected to the first high potential power line VDD1 through a contact hole of the interlayer insulating layer 113 and the other end may be directly connected to the driving drain electrode DDE. The auxiliary high potential power line VDDA and the driving drain electrode DDE may be integrally formed. Accordingly, the auxiliary high potential power line VDDA may transmit the high potential power voltage of the high potential power line VDD to the driving drain electrode DDE.

Next, the first passivation layer 114 is disposed on the driving transistor DT, the first transistor T1, the second transistor T2, the third transistor T3, the storage capacitor Cst, the scan line SL, the data line DL, the reference line RL, the emission control line EML, the high potential power line VDD, and the low potential power line VSS. The first passivation layer 114 is an insulating layer which protects components below the first passivation layer 114 and may be configured by a single layer or a double layer of silicon oxide (SiOx) or silicon nitride (SiNx), but is not limited thereto.

The first planarization layer 115 is disposed on the first passivation layer 114. The first planarization layer 115 may planarize an upper portion of the substrate 110 on which the plurality of transistors and the storage capacitor Cst are disposed. The first planarization layer 115 may be configured by a single layer or a double layer, and for example, may be formed of photoresist or an acrylic organic material, but is not limited thereto.

A plurality of reflective electrodes is disposed on the first planarization layer 115. The plurality of reflective electrodes includes a first reflective electrode RE1, a second reflective electrode RE2, and a third reflective electrode RE3. The plurality of reflective electrodes electrically connects the driving transistor DT, the third transistor T3, and the high potential power line VDD to the light emitting diode 120 and the diode 130. The plurality of reflective electrodes may serve as reflectors which reflect light emitted from the light emitting diode 120 to an upper portion of the substrate 110, simultaneously. The plurality of reflective electrodes may be formed of opaque conductive materials having a high reflection efficiency, such as titanium (Ti), gold (Au), silver (Ag), copper (Cu), or an allow thereof, but is not limited thereto.

The first reflective electrode RE1 is disposed so as to overlap the light emitting diode 120. The first reflective electrode RE1 may reflect the light emitted from the light emitting diode 120 to the upper portion of the substrate 110. The first reflective electrode RE1 may be electrically connected to the driving source electrode DSE through a contact hole formed in the first planarization layer 115 and the first passivation layer 114. The first reflective electrode RE1 may be electrically connected to the first electrode 124 of the light emitting diode 120 through a first connection electrode CE1 to be described below.

At least a part of the second reflective electrode RE2 is disposed so as to overlap the third drain electrode DE3 of the third transistor T3. The second reflective electrode RE2 may be electrically connected to a third drain electrode DE3 through a contact hole of the first planarization layer 115 and the first passivation layer 114. The second reflective electrode RE2 may be electrically connected to the second electrode 125 of the light emitting electrode 120 and a second diode electrode 134 of the diode 130 through a second connection electrode CE2 to be described below.

At least a part of the third reflective electrode RE3 is disposed so as to overlap the auxiliary high potential power line VDDA. The third reflective electrode RE3 may be electrically connected to the auxiliary high potential power line VDDA through a contact hole of the first planarization layer 115 and the first passivation layer 114. The third reflective electrode RE3 may be electrically connected to the first diode electrode 133 of the diode 130 through the third connection electrode CE3 to be described below.

A second passivation layer 116 is disposed on the plurality of reflective electrodes. The second passivation layer 116 is an insulating layer which protects components below the second passivation layer 116 and may be configured by a single layer or a double layer of silicon oxide (SiOx) or silicon nitride (SiNx), but is not limited thereto.

An adhesive layer 117 is disposed on the second passivation layer 116. The adhesive layer 117 is formed on the front surface of the substrate 110 to fix the light emitting diode 120 and the diode 130 disposed on the adhesive layer 117 onto the substrate 110. The adhesive layer 117 may be formed of a photo curable adhesive material which is cured by light. For example, the adhesive layer 117 may be selected from any one of adhesive polymer, epoxy resist, UV resin, polyimide, acrylate, urethane, and polydimethylsiloxane (PDMS), but is not limited thereto.

The light emitting diode 120 is disposed on the adhesive layer 117. The light emitting diode 120 is an element which is supplied with a driving current I_{LED} to emit light and may include a light emitting diode 120 which emits red light, green light, and blue light and implement various colored light including white by a combination thereof.

The light emitting diode 120 includes a first semiconductor layer 121, an emission layer 122, a second semiconductor layer 123, a first electrode 124, a second electrode 125, and an encapsulation film 126.

The first semiconductor layer 121 is disposed on the adhesive layer 117 and the second semiconductor layer 123 is disposed on the first semiconductor layer 121. The first semiconductor layer 121 and the second semiconductor layer 123 may be layers formed by doping n-type and p-type impurities into a specific material. For example, each of the first semiconductor layer 121 and the second semiconductor layer 123 may be a layer doped with n-type and p-type impurities into a material such as gallium nitride (GaN), indium aluminum phosphide (InAlP), or gallium arsenide (GaAs). The p-type impurity may be magnesium (Mg), zinc (Zn), and beryllium (Be), and the n-type impurity may be silicon (Si), germanium, and tin (Sn), but is not limited thereto.

The emission layer 122 is disposed between the first semiconductor layer 121 and the second semiconductor layer 123. The emission layer 122 is supplied with holes and electrons from the first semiconductor layer 121 and the second semiconductor layer 123 to emit light. The emission layer 122 may be formed by a single layer or a multi-quantum well (MQW) structure, and for example, may be formed of indium gallium nitride (InGaN) or gallium nitride (GaN), but is not limited thereto.

The first electrode 124 is disposed on the first semiconductor layer 121. The first electrode 124 is an electrode which electrically connects the driving transistor DT and the first semiconductor layer 121. In this case, the first semiconductor layer 121 is a semiconductor layer doped with a p-type impurity and the first electrode 124 may be an anode. The first electrode 124 may be disposed on a top surface of the first semiconductor layer 121 which is exposed from the emission layer 122 and the second semiconductor layer 123. The first electrode 124 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second electrode 125 is disposed on the second semiconductor layer 123. The second electrode 125 may be disposed on the top surface of the second semiconductor layer 123. The second electrode 125 is an electrode which electrically connects the third transistor T3 and the second semiconductor layer 123. In this case, the second semiconductor layer 123 is a semiconductor layer doped with an n-type impurity and the second electrode 125 may be a cathode. The second electrode 125 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

Next, the encapsulation film 126 which encloses the first semiconductor layer 121, the emission layer 122, the second semiconductor layer 123, the first electrode 124, and the second electrode 125 is disposed. The encapsulation film 126 is formed of an insulating material to protect the first semiconductor layer 121, the emission layer 122, and the second semiconductor layer 123. In the encapsulation film 126, a contact hole which exposes the first electrode 124 and the second electrode 125 is formed so that the first electrode 124 and the second electrode 125 may be electrically connected to the first connection electrode CE1 and the second connection electrode CE2, respectively.

Next, the emission control element 130 is disposed on the adhesive layer 117. The emission control element 130 is connected between the high potential power line VDD and the second electrode 125 of the light emitting diode 120 to transmit the high potential power voltage to the second electrode 125 of the light emitting diode 120. The emission control element 130 may be configured by a diode 130. The diode 130 includes a first diode semiconductor layer 131, a second diode semiconductor layer 132, a first diode electrode 133, a second diode electrode 134, and a diode encapsulation film 135.

The first diode semiconductor layer 131 is disposed on the adhesive layer 117 and the second diode semiconductor layer 132 is disposed on the first diode semiconductor layer 131. The first diode semiconductor layer 131 and the second diode semiconductor layer 132 may be layers formed by doping n-type and p-type impurities into a specific material. For example, each of the first diode semiconductor layer 131 and the second diode semiconductor layer 132 may be a layer doped with n-type and p-type impurities into a material such as gallium nitride (GaN), indium aluminum phosphide (InAlP), or gallium arsenide (GaAs). The p-type impurity may be magnesium (Mg), zinc (Zn), and beryllium (Be), and the n-type impurity may be silicon (Si), germanium, and tin (Sn), but is not limited thereto.

The first diode electrode 133 is disposed on the first diode semiconductor layer 131. The first diode electrode 133 is an electrode which electrically connects the high potential power line VDD and the first diode semiconductor layer 131. In this case, the first diode semiconductor layer 131 is a semiconductor layer doped with a p-type impurity and the first diode electrode 133 may be an anode. The first diode electrode 133 may be disposed on a top surface of the first diode semiconductor layer 131 which is exposed from the second diode semiconductor layer 132. The first diode electrode 133 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second diode electrode 134 is disposed on the second diode semiconductor layer 132. The second diode electrode 134 may be disposed on the top surface of the second diode semiconductor layer 132. The second diode electrode 134 is an electrode which electrically connects the third transistor T3 and the second diode semiconductor layer 132. In this case, the second diode semiconductor layer 132 is a semiconductor layer doped with a n-type impurity and the second diode electrode 134 may be a cathode. The second diode electrode 134 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

Next, a diode encapsulation film 135 which encloses the first diode semiconductor layer 131, the second diode semiconductor layer 132, the first diode electrode 133, and the second diode electrode 134 is disposed. The diode encapsulation film 135 is formed of an insulating material to protect the first diode semiconductor layer 131 and the second diode semiconductor layer 132. In the diode encapsulation film 135, a contact hole which exposes the first diode electrode 133 and the diode second electrode 134 is formed so that the first diode electrode 133 and the second diode electrode 134 may be electrically connected to the third connection electrode CE3 and the second connection electrode CE2, respectively.

In the meantime, a part of a side surface of the first semiconductor layer 121 of the light emitting diode 120 may be exposed from the encapsulation film 126. The light emitting diode 120 manufactured on a wafer is separated from the wafer to be transferred onto the display panel PN. However, during the process of separating the light emitting diode 120 from the wafer, a part of the encapsulation film 126 may be torn. For example, a part of the encapsulation film 126 which is adjacent to a lower edge of the first semiconductor layer 121 of the light emitting diode 120 is torn during the process of separating the light emitting diode 120 from the wafer. Accordingly, a part of a lower side surface of the first semiconductor layer 121 may be exposed to the outside. Even though the lower portion of the light emitting diode 120 is exposed from the encapsulation film 126, the first connection electrode CE1 and the second connection electrode CE2 are formed after forming a second planarization layer 118 which covers the side surface of the first semiconductor layer 121. Accordingly, a short defect between the first semiconductor layer 121, the second semiconductor layer 123, the first connection electrode CE1, and the second connection electrode CE2 may be reduced.

Further, a part of a side surface of the first diode semiconductor layer 131 of the emission control element 30 may also be exposed from the diode encapsulation film 135 in the same way as the light emitting diode 120. During a process of separating the emission control element 130 from the wafer, a part of the diode encapsulation film 135 is torn off so that a lower side surface of the first diode semiconductor layer 131 may be exposed to the outside. The second connection electrode CE2 and the third connection electrode CE3 are formed after forming the second planarization layer 118 which covers the emission control element 130. Therefore, a short defect between the first diode semiconductor layer 131, the second diode semiconductor layer 132, the second connection electrode CE2, and the third connection electrode CE3 may be reduced.

The second planarization layer 118 is disposed on the light emitting diode 120 and the emission control element 130. The second planarization layer 118 may be disposed so as to cover at least a part of the light emitting diode 120 and the emission control element 130. The second planarization layer 118 may be configured by a single layer or a double layer, and for example, may be formed of photoresist or an acrylic organic material, but is not limited thereto.

A plurality of connection electrodes is disposed on the second planarization layer 118. The plurality of connection electrodes is electrodes which electrically connect the light emitting diode 120 and the emission control element 130 to the pixel circuit and the plurality of wiring lines. The plurality of connection electrodes includes a first connection electrode CE1, a second connection electrode CE2, and a third connection electrode CE3. The plurality of connection electrodes may be formed of a transparent conductive material, such as indium tin oxide (ITO) or indium zinc oxide (IZO), but is not limited thereto.

First, the first connection electrode CE1 is an electrode for electrically connecting the light emitting diode 120 and the driving transistor DT. The first connection electrode CE1 is disposed so as to cover the light emitting diode 120 and may be electrically connected to the first electrode 124 of the light emitting diode 120 exposed from the second planarization layer 118. The first connection electrode CE1 may be electrically connected to the first reflective electrode RE1 through a contact hole of the second passivation layer 116 and the second planarization layer 118. The first reflective electrode CE1 is an electrode which is electrically connected to the driving source electrode DSE so that the first electrode 124 of the light emitting diode 120 and the driving source electrode DSE may be electrically connected to each other through the first reflective electrode RE1 and the first connection electrode CE1.

The second connection electrode CE2 is an electrode which electrically connects the light emitting diode 120, the emission control element 130, and the third transistor T3. The second connection electrode CE2 is disposed so as to cover the light emitting diode 120 and may be electrically connected to the second electrode 125 of the light emitting diode 120 exposed from the second planarization layer 118. The second connection electrode CE2 is disposed so as to cover the emission control element 130 and may be electrically connected to the second diode electrode 134 of the emission control element 130 exposed from the second planarization layer 118. Finally, the second connection electrode CE2 may be electrically connected to the second reflective electrode RE2 through a contact hole of the second passivation layer 116 and the second planarization layer 118. Accordingly, the second electrode 125 of the light emitting diode 120 and the second diode electrode 134 of the emission control element 130 may be electrically connected to the third drain electrode DE3 of the third transistor T3 through the second connection electrode CE2 and the second reflective electrode RE2.

The third connection electrode CE3 is an electrode for electrically connecting the emission control element 130 and the high potential power line VDD. The third connection electrode CE3 is disposed so as to cover the emission control element 130 and may be electrically connected to the first diode electrode 133 of the emission control element 130 exposed from the second planarization layer 118. The third connection electrode CE3 may be electrically connected to the third reflective electrode RE3 through a contact hole of the second planarization layer 118 and the second passivation layer 116. Accordingly, the first diode electrode 133 of the emission control element 130 may be electrically connected to the first high potential power line VDD1 of the high potential power line VDD through the third connection electrode CE3, the third reflective electrode RE3, and the auxiliary high potential power line VDDA.

Further, even though it is not illustrated in the drawing, a bank may be disposed on the second planarization layer 118 in an area between the plurality of sub pixels SP. The bank is disposed at the boundary between the plurality of sub pixels SP to reduce the color mixture between the plurality of sub pixels SP. The bank may be formed of an opaque material and for example, may be formed of black resin, but is not limited thereto.

Even though it is not illustrated in the drawings, a protection layer may be disposed on the plurality of connection electrodes and the bank. The protection layer is a layer for protecting configurations below the protection layer. The protection layer may be configured as a single layer or a double layer, for example, may be formed of benzocyclobutene, translucent epoxy, photoresist, an acryl-based organic material or an inorganic material such as silicon oxide (SiOx), or silicon nitride (SiNx), but is not limited thereto.

Accordingly, in the display device 100 according to the exemplary embodiment of the present disclosure, the light emitting diode 120 and the emission control element 130 are transferred onto the adhesive layer 117 together to simplify a forming process of the emission control element 130. The emission control element 130 may be formed of the substantially same structure as the light emitting diode 120 except that the emission layer 122 is not included and the light emitting diode 120 and the emission control element 130 may be transferred onto the adhesive layer 117 using the same process. Therefore, the forming process of the emission control element 130 may be simplified and the emission control element 130 is vertically laminated on the other transistor to minimize an area occupied by the emission control element 130 on the plane.

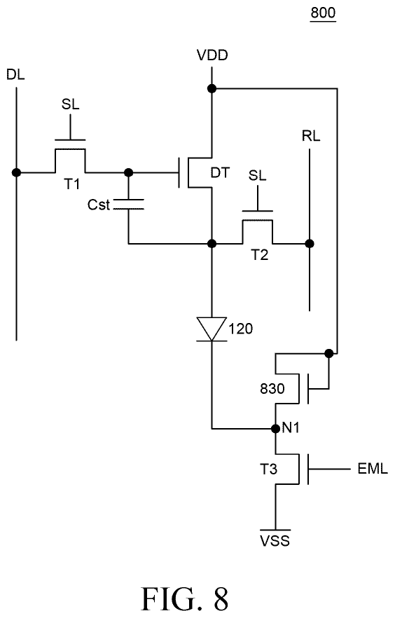

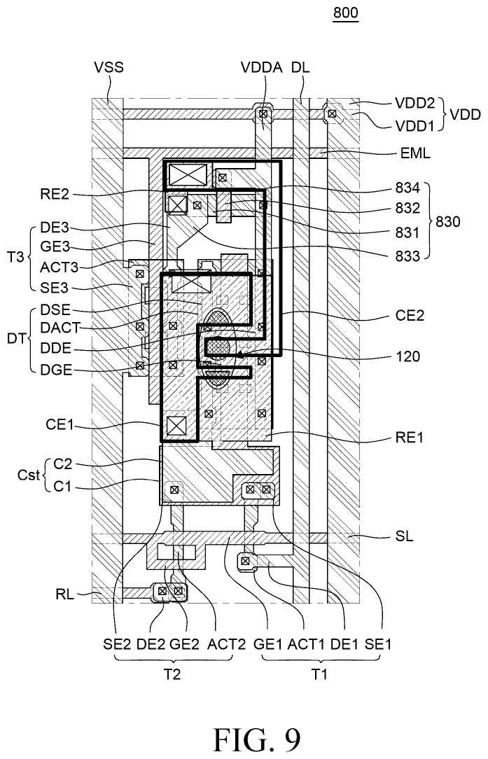

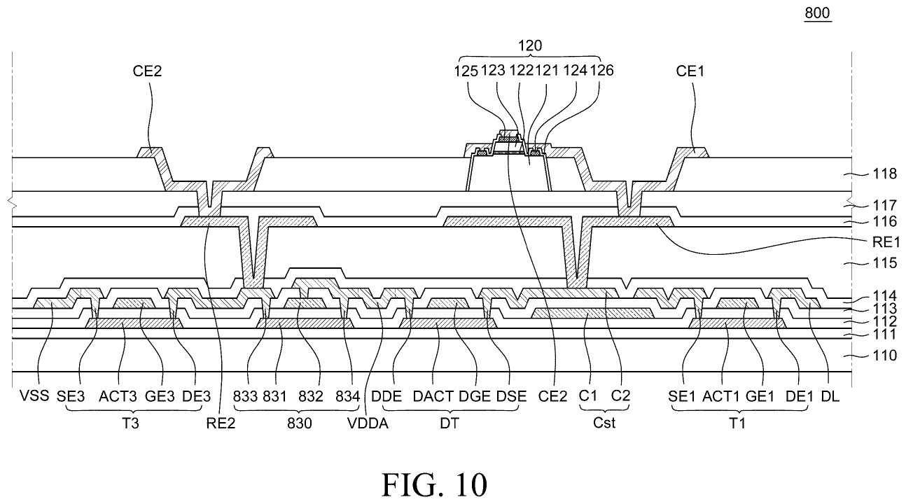

FIG. 8 is a circuit diagram of a sub pixel of a display device according to another exemplary embodiment of the present disclosure. FIG. 9 is a plan view of a sub pixel of a display device according to another exemplary embodiment of the present disclosure. FIG. 10 is a cross-sectional view of a sub pixel of a display device according to another exemplary embodiment of the present disclosure. A display device 800 of FIGS. 8 to 10 is substantially the same as the display device 100 of FIGS. 1 to 7 except that an emission control element 830 of an emission control circuit is configured by a transistor in a diode connection state and a reflective electrode and a connection electrode are different. A redundant description will be omitted.

Referring to FIG. 8, an emission control element 830 of the emission control circuit may be configured by a transistor in a diode connection state. The emission control element 830 is configured by a transistor in a diode connection state to flow a current from the high potential power line VDD to the first node N1. The emission control element 830 may serve as a diode by electrically connecting a fourth gate electrode 832 to a fourth drain electrode 834 to flow a current only in one direction.

Referring to FIGS. 8 to 10, the emission control element 830 includes a fourth active layer 831, the fourth gate electrode 832, a fourth source electrode 833, and the fourth drain electrode 834.

The fourth active layer 831 is disposed on the buffer layer 111. The fourth active layer 831 may be formed of a semiconductor material such as an oxide semiconductor, amorphous silicon, or polysilicon, but is not limited thereto.

The gate insulating layer 112 is disposed on the fourth active layer 831 and the fourth gate electrode 832 is disposed on the gate insulating layer 112. The fourth gate electrode 832 may be electrically connected to an auxiliary low potential power line VSS. The fourth gate electrode 832 may be configured by a conductive material such as copper (Cu), aluminum (Al), molybdenum (Mo), nickel (Ni), titanium (Ti), chrome (Cr), or an alloy thereof, but is not limited thereto.

The interlayer insulating layer 113 is disposed on the fourth gate electrode 832 and the fourth source electrode 833 and the fourth drain electrode 834 are disposed on the interlayer insulating layer 113. The fourth source electrode 833 and the fourth drain electrode 834 may be electrically connected to the fourth active layer 831 through a contact hole of the interlayer insulating layer 113 and the gate insulating layer 112. The fourth source electrode 833 is integrally formed with the third drain electrode DE3 to be electrically connected to the third drain electrode DE3. The fourth source electrode 833 may be electrically connected to the second electrode 125 of the light emitting electrode 120 through a second reflective electrode RE2 and the second connection electrode CE2. The fourth drain electrode 834 may be electrically connected to the auxiliary high potential power line VDDA. The fourth drain electrode 834 may be integrally formed with the driving drain electrode DDE to be electrically connected to the driving drain electrode DDE. The fourth source electrode 833 and the fourth drain electrode 834 may be configured by a conductive material, such as copper (Cu), aluminum (Al), molybdenum (Mo), nickel (Ni), titanium (Ti), chrome (Cr), or an alloy thereof, but are not limited thereto.

In the meantime, the fourth drain electrode 834 and the fourth gate electrode 832 are electrically connected to the auxiliary high potential power line VDDA. Therefore, the fourth drain electrode 834 and the fourth gate electrode 832 may be electrically connected to each other through the auxiliary high potential power line VDDA and the emission control element 830 may be implemented in a diode connection state. In the emission control element 830 in the diode connection state, the fourth gate electrode 832 is electrically connected to the high potential power line VDD so that the emission control element 830 may maintain a turn-on state at all times. Accordingly, the emission control element 830 which maintains a turn-on state may allow the current to flow only to the first node N1 from the high potential power line VDD.

Next, the first passivation layer 114 and the first planarization layer 115 are disposed on the emission control element 830 and the plurality of reflective electrodes is disposed on the first planarization layer 115. The plurality of reflective electrodes includes a first reflective electrode RE1 and a second reflective electrode RE2. The plurality of reflective electrodes electrically connects the driving transistor DT, the third transistor T3, and the emission control element 830 to the light emitting diode 120 and may serve as a reflector which reflects light emitted from the light emitting diode 120 to an upper portion of the substrate 110, simultaneously. The plurality of reflective electrodes may be formed of opaque conductive materials having a high reflection efficiency, such as titanium (Ti), gold (Au), silver (Ag), copper (Cu), or an allow thereof, but is not limited thereto.

The first reflective electrode RE1 is disposed so as to overlap the light emitting diode 120. The first reflective electrode RE1 may reflect the light emitted from the light emitting diode 120 to the upper portion of the substrate 110. The first reflective electrode RE1 may be electrically connected to the driving source electrode DSE through a contact hole formed in the first planarization layer 115 and the first passivation layer 114. The first reflective electrode RE1 may be electrically connected to the first electrode 124 of the light emitting diode 120 through a first connection electrode CE1.

At least a part of the second reflective electrode RE2 is disposed so as to overlap the third drain electrode DE3 of the third transistor T3 and the fourth source electrode 833. The second reflective electrode RE2 may be electrically connected to a third drain electrode DE3 and the fourth source electrode 833 through a contact hole of the first planarization layer 115 and the first passivation layer 114. The second reflective electrode RE2 may be electrically connected to the second electrode 125 of the light emitting diode 120 through a second connection electrode CE2.

Next, the second passivation layer 116, the adhesive layer 117, the light emitting diode 120, and the second planarization layer 118 are disposed on the plurality of reflective electrodes and the plurality of connection electrodes is disposed on the second planarization layer 118 and the light emitting diode 120. The plurality of connection electrodes is electrodes for electrically connecting the light emitting diode 120 to the pixel circuit. The plurality of connection electrodes includes a first connection electrode CE1 and a second connection electrode CE2. The plurality of connection electrodes may be formed of a transparent conductive material, such as indium tin oxide (ITO) or indium zinc oxide (IZO), but is not limited thereto.

The first connection electrodes CE1 is an electrode for electrically connecting the light emitting diode 120 and the driving transistor DT. The first connection electrode CE1 is disposed so as to cover the light emitting diode 120 and may be electrically connected to the first electrode 124 of the light emitting diode 120 exposed from the second planarization layer 118. The first connection electrode CE1 may be electrically connected to the first reflective electrode RE1 through a contact hole of the second passivation layer 116 and the second planarization layer 118. The first reflection electrode RE1 is an electrode which is electrically connected to the driving source electrode DSE so that the first electrode 124 of the light emitting diode 120 and the driving source electrode DSE may be electrically connected to each other through the first reflective electrode RE1 and the first connection electrode CE1.

The second connection electrode CE2 is an electrode which electrically connects the light emitting diode 120, the third transistor T3, and the emission control element 830. The second connection electrode CE2 is disposed so as to cover the light emitting diode 120 and may be electrically connected to the second electrode 125 of the light emitting diode 120 exposed from the second planarization layer 118. The second connection electrode CE2 may be electrically connected to the second reflective electrode RE2 through a contact hole of the second passivation layer 116 and the second planarization layer 118. Accordingly, the second electrode 125 of the light emitting diode 120 may be electrically connected to the third drain electrode DE3 of the third transistor T3 and the fourth source electrode 833 of the emission control element 830 through the second connection electrode CE2 and the second reflective electrode RE2.

The third transistor T3 may be turned on only in the emission period Emission when the light emitting diode 120 emits light. In the emission period Emission, the third transistor T3 is turned on so that the second electrode 125 of the light emitting diode 120 may be electrically connected to the low potential power line VSS. Accordingly, as the second electrode 125 of the light emitting diode 120 is connected to the low potential power line VSS, the driving current I_{LED} may flow from the first electrode 124 to the second electrode 125 of the light emitting diode 120 and the light emitting diode 120 may emit light.

The third transistor T3 may be turned off in the non-emission period Black when the light emitting diode 120 does not emit light. In the non-emission period Black, the third transistor T3 is turned off so that the second electrode 125 of the light emitting diode 120 may be separated from the low potential power line VSS. Instead, during the non-emission period Black, the high potential power line VDD and the second electrode 125 of the light emitting diode 120 may be electrically connected by the emission control element 830.

In the meantime, even though in the present disclosure, it has been described that the fourth drain electrode 834 is electrically connected to the high potential power line VDD, the fourth drain electrode 834 may be connected to a wiring line to which another constant voltage is applied. For example, the fourth drain electrode 834 may be connected to an initialization line and the emission control element 830 transmits an initialization voltage to the first node N1 during the non-emission period Black so that the light emitting diode 120 does not emit light.

Accordingly, in the display device 800 according to another exemplary embodiment of the present disclosure, the emission control element 830 may be formed by a transistor in a diode connection state. The emission control element 830 may be formed together when the plurality of transistors of the sub pixel SP is formed and the forming process of the emission control element 830 may be simplified. Further, the fourth gate electrode 832 and the fourth drain electrode 834 are connected to configure the emission control element 830 in a diode connection state to easily control the current direction between the high potential power line VDD and the first node N1 to one direction. Accordingly, the high potential power voltage may be easily supplied to the second electrode 125 of the light emitting diode 120 during the data writing period Writing and the non-emission period Black using the emission control element 830 in the diode connection state. Further, a defect that the light emitting diode 120 emits light in a period other than the emission period Emission may be suppressed.

The exemplary embodiments of the present disclosure can also be described as follows:

According to an aspect of the present disclosure, a display device includes a display panel which includes a plurality of sub pixels, a light emitting diode which is disposed in each of the plurality of sub pixels and is configured to be controlled in response to an emission period and a non-emission period, a driving transistor connected to a first electrode of the light emitting diode, and an emission control circuit which is connected between a second electrode of the light emitting diode and a high potential power line and between the second electrode and a low potential power line. The emission control circuit is configured to connect the second electrode of the light emitting diode to any one of the high potential power line and the low potential power line in response to each of the emission period and the non-emission period and the emission control circuit includes an emission control element which is formed by any one of a diode or a transistor in a diode connection state and an emission control transistor.

The emission control element may be an element which controls a current to flow from the high potential power line to the second electrode.

The emission control transistor may be configured to connect the second electrode and the low potential power line during the emission period of the plurality of sub pixels.

The emission control transistor may be configured to be turned on only during the emission period.

During the non-emission period, a voltage of the first electrode may be equal to or lower than a voltage of the second electrode.

The display panel may further include a substrate disposed below the driving transistor and the emission control transistor, an adhesive layer disposed on the driving transistor and the emission control transistor, and a planarization layer disposed on the light emitting diode, and the light emitting diode may be disposed between the adhesive layer and the planarization layer.

The light emitting diode may further include a first semiconductor layer, an emission layer disposed on the first semiconductor layer, a second semiconductor layer which is disposed on the emission layer and has a top surface on which the second electrode is disposed, and a first electrode disposed on the first semiconductor layer.

The emission control element may be a diode.

The diode may include a first diode semiconductor layer, a second diode semiconductor layer disposed on the first diode semiconductor layer, a first diode electrode disposed on the first diode semiconductor layer, and a second diode electrode disposed on the second diode semiconductor layer, and the diode may be disposed between the adhesive layer and the planarization layer.

The display panel may further include a first reflective electrode which is disposed between the adhesive layer and the driving transistor and is electrically connected to the driving transistor, a first connection electrode which is disposed on the planarization layer and electrically connects the first reflective electrode and the first electrode, a second reflective electrode which is disposed between the adhesive layer and the driving transistor and is electrically connected to the emission control transistor, a second connection electrode which is disposed on the planarization layer and electrically connects the second reflective electrode, the second electrode, and the second diode electrode, a third reflective electrode which is disposed between the adhesive layer and the driving transistor and is electrically connected to the high potential power line, and a third connection electrode which is disposed on the planarization layer and electrically connects the third reflective electrode and the first diode electrode.

The emission control element may be the transistor in the diode connection state.

The transistor in the diode connection state may include an active layer disposed on the substrate, a gate electrode disposed on the active layer, a source electrode which is disposed on the gate electrode and is electrically connected to the active layer and the emission control transistor, and a drain electrode which is disposed on the gate electrode and is electrically connected to the active layer and the gate electrode, and the transistor in the diode-connection state may be disposed between the substrate and the adhesive layer.

The display panel may further include a first reflective electrode which is disposed between the adhesive layer and the driving transistor and is electrically connected to the driving transistor, a first connection electrode which is disposed on the planarization layer and electrically connects the first reflective electrode and the first electrode, a second reflective electrode which is disposed between the adhesive layer and the driving transistor and is electrically connected to the emission control transistor and the transistor in the diode connection state, and a second connection electrode which is disposed on the planarization layer and electrically connects the second reflective electrode and the second electrode.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a display panel which includes a plurality of sub pixels;
a light emitting diode which is disposed in each of the plurality of sub pixels and is configured to be controlled in response to an emission period and a non-emission period, the light emitting diode including a first electrode and a second electrode;
a driving transistor electrically connected to the first electrode of the light emitting diode; and
an emission control circuit which is electrically connected between the second electrode of the light emitting diode and a high potential power line and between the second electrode and a low potential power line, the emission control circuit including an emission control element and an emission control transistor,
wherein the emission control circuit is configured to electrically connect the second electrode of the light emitting diode to any one of the high potential power line and the low potential power line in response to each of the emission period and the non-emission period.

2. The display device according to claim 1, wherein the emission control element is formed by any one of a diode or a transistor in a diode connection state.

3. The display device according to claim 1, wherein the emission control element is an element which controls a current to flow from the high potential power line to the second electrode.

4. The display device according to claim 1, wherein the emission control transistor is configured to electrically connect the second electrode and the low potential power line during the emission period of the plurality of sub pixels.

5. The display device according to claim 4, wherein the emission control transistor is configured to be turned on only during the emission period.

6. The display device according to claim 4, wherein during the non-emission period, a voltage of the first electrode is equal to or lower than a voltage of the second electrode.

7. The display device according to claim 1, wherein the display panel further includes:
a substrate disposed below the driving transistor and the emission control transistor;
an adhesive layer disposed on the driving transistor and the emission control transistor; and
a planarization layer disposed on the light emitting diode, and
wherein the light emitting diode is disposed between the adhesive layer and the planarization layer.

8. The display device according to claim 7, wherein the light emitting diode further includes:
a first semiconductor layer;
an emission layer disposed on the first semiconductor layer;
a second semiconductor layer which is disposed on the emission layer and has a top surface on which the second electrode is disposed; and
a first electrode disposed on the first semiconductor layer.

9. The display device according to claim 8, wherein the emission control element is a diode.

10. The display device according to claim 9, wherein the diode includes:
a first diode semiconductor layer;
a second diode semiconductor layer disposed on the first diode semiconductor layer;
a first diode electrode disposed on the first diode semiconductor layer; and
a second diode electrode disposed on the second diode semiconductor layer,
wherein the diode is disposed between the adhesive layer and the planarization layer.

11. The display device according to claim 10, wherein the display panel further includes:
a first reflective electrode which is disposed between the adhesive layer and the driving transistor and is electrically connected to the driving transistor;
a first connection electrode which is disposed on the planarization layer and electrically connects the first reflective electrode and the first electrode;
a second reflective electrode which is disposed between the adhesive layer and the driving transistor and is electrically connected to the emission control transistor;
a second connection electrode which is disposed on the planarization layer and electrically connects the second reflective electrode, the second electrode, and the second diode electrode;
a third reflective electrode which is disposed between the adhesive layer and the driving transistor and is electrically connected to the high potential power line; and
a third connection electrode which is disposed on the planarization layer and electrically connects the third reflective electrode and the first diode electrode.

12. The display device according to claim 8, wherein the emission control element is the transistor in the diode connection state.

13. The display device according to claim 12, wherein the transistor in the diode connection state includes:
an active layer disposed on the substrate;
a gate electrode disposed on the active layer;
a source electrode which is disposed on the gate electrode and is electrically connected to the active layer and the emission control transistor; and
a drain electrode which is disposed on the gate electrode and is electrically connected to the active layer and the gate electrode,
wherein the transistor in the diode-connection state is disposed between the substrate and the adhesive layer.

14. The display device according to claim 13, wherein the display panel further includes:
a first reflective electrode which is disposed between the adhesive layer and the driving transistor and is electrically connected to the driving transistor;
a first connection electrode which is disposed on the planarization layer and electrically connects the first reflective electrode and the first electrode;
a second reflective electrode which is disposed between the adhesive layer and the driving transistor and is electrically connected to the emission control transistor and the transistor in the diode connection state; and
a second connection electrode which is disposed on the planarization layer and electrically connects the second reflective electrode and the second electrode.
